(19) United States
(12) Patent Application Publication
(10) Pub. No.: US 2010/0314683 A1
(43) Pub. Date: Dec. 16, 2010

(54) SEMICONDUCTOR DEVICE

(75) Inventor: Shinichiro Yanagi, Kanagawa (JP)

Correspondence Address: MCDERMOTT WILL & EMERY LLP, 600 13TH STREET, N.W., WASHINGTON, DC, 20005-3096, US

(73) Assignee: RENESAS ELECTRONICS CORPORATION

(21) Appl. No.: 12/782,475

(22) Filed: May 18, 2010

(30) Foreign Application Priority Data
Jun. 16, 2009 (JP) 2009-143591

(51) Int. Cl. H01L 29/78

(52) U.S. Cl. 257/339; 257/E29.261; 257/335

(57) ABSTRACT

Provided is a semiconductor device which scarcely malfunctions even when the device is used as a high-side element, and can keep a high breakdown voltage. In a semiconductor substrate having a main surface, a first p⁻ epitaxial region is formed. At the main surface side of the first p⁻ epitaxial region, a second p⁻ epitaxial region is formed. At the main surface side of the second p⁻ epitaxial region, an n-type drift region and a p-type body region are formed. Between the first and second p⁻ epitaxial regions, an n⁺ buried region having a floating potential is formed to isolate these regions electrically from each other. Between n⁺ buried region and the second p⁻ epitaxial region, a p⁺ buried region is formed which has a higher p-type impurity concentration than the second p⁻ epitaxial region.

### CROSS-REFERENCE TO RELATED APPLICATIONS

The disclosure of Japanese Patent Application No. 2009-143591 filed on Jun. 16, 2009 including the specification, drawings and abstract is incorporated herein by reference in its entirety.

### BACKGROUND OF THE INVENTION

The present invention relates to a semiconductor device, in particular, a semiconductor device having a lateral element.

A general structure of a high-breakdown-voltage laterally diffused metal oxide semiconductor (MOS) transistor (LDMOS transistor) is the structure of a reduced surface field (RESURF) MOS transistor (see FIG. 1 in Non-patent document 1 (see below)). In the case of optimizing, in this structure, the profile of the concentration of impurities in its n-type drift region, a depletion layer spreads also in a junction between the n-type drift region and a p⁻ epitaxial region underneath the region when a reverse vias is applied to the structure. As a result, the structure can have a high breakdown voltage.

However, when a transistor having a structure wherein a source electrode (or a p-type body region) and a p⁻ epitaxial region are not isolated electrically from each other is used as a high-side element, the ground potential of the p⁻ epitaxial region is followed by a power source voltage applied to the source electrode, so as to be made instable. This causes a low-side element to malfunction. For this reason, there is caused a problem that such a transistor cannot be used as a high-side element and the use thereof is limited to use as a low-side element.

Against this problem, as a high-breakdown-voltage MOS transistor structure that can be used as a high-side element also, two structure are known which each have an n-type isolation region for isolating a p⁻ epitaxial region and a source electrode electrically from each other.

The first structure of the two is a transistor structure of a high-breakdown-voltage MOS transistor in which an n-type isolation region as described above is formed and further an n-type drift region is not only arranged underneath an n-type drain region but also extended around the underneath of a p-type body region in order to reach the n-type isolation region (see FIG. 3 in Non-patent document 2).

The second structure is a transistor structure of a high-breakdown-voltage MOS transistor in which an n-type isolation region as described above is formed and further the n-type isolation region is short-circuited with a drain electrode (see FIG. 1 in Patent document 1).

Patent document 1: U.S. Pat. No. 7,095,092
Non-patent document 1: R. Zhu et al., “A 65 V, 0.56 mΩ·cm² Resurf LDMOS in a 0.35 μm CMOS Process”, IEEE ISPSD 2000, pp. 335-338
Non-patent document 2: Y. Park et al., “BD180—a new 0.18 μm BCD (Bipolar-CMOS-DMOS) Technology from 7V to 60V”, IEEE ISPSD 2008, pp. 64-67

### SUMMARY OF THE INVENTION

However, the first structure is not any RESURF structure; thus, when a reverse bias is applied thereto, an electric field concentrates into the vicinity of a junction between the p-type body region and the n-type drift region, thereby resulting in a problem that the structure has a lower breakdown voltage than the above-mentioned RESURF structure having no n-type isolation region. In order to make the first structure so as to give a high breakdown voltage, it is necessary to decrease the dopant concentration in the n-type drift region. However, the decrease results in a rise in the on-resistance of the transistor. As a result, there is caused a problem that the element size should be made large.

In the second structure, its n-type isolation region is at a level of the drain potential. Thus, when a reverse bias is applied thereto, a depletion layer generated in a junction region between the n-type isolation region and the p⁻ epitaxial region and a depletion layer generated in a junction region between the p⁻ epitaxial region and the n-type drift region undergo punchthrough antecedently. Thus, a potential difference is generated between the n-type isolation region and the source region. As a result thereof, electric-field-concentration is caused in the vicinity of the junction between the p-type body region and the n-type drift region, thereby causing a problem that the structure has a lower breakdown voltage than the above-mentioned RESURF structure having no n-type isolation region.

In light of the above-mentioned problems, the present invention has been made, and an object thereof is to provide a semiconductor device which scarcely malfunctions even when the device is used as a high-side element, and can keep a high breakdown voltage.

An aspect of the invention is a semiconductor device having a semiconductor substrate, first conductive type first, second, fourth and sixth regions, and second conductive type third and fifth regions. The semiconductor substrate has a main surface. The first region is formed in the semiconductor substrate. The second region is formed in the semiconductor substrate and at the main surface side of the first region. The third region is formed in the semiconductor substrate and at the main surface side of the second region, and is further combined with the second region to form a pn junction therebetween. The fourth region is formed in the semiconductor substrate to contact the second region and be further adjacent to the third region at the main surface side of the second region, and further has a higher first conductive type impurity concentration than that of the second region. The fifth region is formed in the semiconductor substrate between the first region and the second region to isolate the first region and the second region electrically from each other, and is further formed to have a floating potential. The sixth region is formed in the semiconductor substrate between the fifth region and the second region and further has a higher first conductive type impurity concentration than that of the second region.

According to the aspect of the invention, the first conductive type first region and second region are isolated electrically from each other by the second conductive type fifth region. Therefore, even when the semiconductor device is used as a high-side element, malfunctions thereof can be reduced.

The third region is combined with the second region to form the pn junction, which extends in the direction along the main surface. Moreover, the second region has a lower impurity concentration than that of the fourth region. Therefore, when a reverse bias is applied to the semiconductor device, a depletion layer spreads from the pn junction between the third and second regions toward the second region, whereby the device can have a high breakdown voltage.

Further, the sixth region, which has a higher impurity concentration than that of the second region, is formed between the fifth region and the second region. The sixth region restrains the depletion layer, which is spread from the pn junction between the third and second regions toward the second region by the reverse bias, from linking with a depletion layer generated in the pn junction between the fifth and sixth regions. In this way, the generation of punchthrough is restrained so that the semiconductor device can keep a high breakdown voltage.

### BRIEF DESCRIPTION OF THE DRAWINGS

FIG. 1 is a sectional view which schematically illustrates the structure of a semiconductor device in Embodiment 1 of the invention.

FIG. 2(A) is a plan view which schematically illustrates the structure of a semiconductor device in Embodiment 1 of the invention, and FIG. 2(B) is a sectional view thereof.

FIG. 3 is a chart which shows a comparison between an impurity concentration distribution in a region along line III-III in FIG. 1 in a case where a p-type buried region is present, and that in a case where no p-type buried region is present.

FIG. 4 is a schematic sectional view which illustrates a first step in a process for producing a semiconductor device in Embodiment 1 of the invention.

FIG. 5 is a schematic sectional view which illustrates a second step in the process.

FIG. 6 is a schematic sectional view which illustrates a third step in the process.

FIG. 7 is a schematic sectional view which illustrates a fourth step in the process.

FIG. 8 is a schematic sectional view which illustrates a fifth step in the process.

FIG. 9 is a schematic sectional view which illustrates a sixth step in the process.

FIG. 10 is a sectional view which schematically illustrates the structure of Comparative Example 1.

FIG. 11 is a potential chart of the structure of Comparative Example 1 which is in a breakdown state.

FIG. 12 is a circuit diagram which is referred to in order to describe a high-side element and a low-side element.

FIG. 13 is a sectional view which schematically illustrates the structure of Comparative Example 2.

FIG. 14 is a potential chart of the structure of Comparative Example 2 which is in a breakdown state.

FIG. 15 is a sectional view which schematically illustrates the structure of Comparative Example 3.

FIG. 16 is a potential chart of the structure of Comparative Example 3 which is in a breakdown state.

FIG. 17 is a potential chart of the structure of the semiconductor device in Embodiment 1 of the invention, which is illustrated in FIG. 1, when the device is in a breakdown state.

FIG. 18 is a chart showing the distribution state of a depletion layer in the semiconductor device in Embodiment 1 of the invention, which is illustrated in FIG. 1, when the device is in the breakdown state.

FIG. 19 is a sectional perspective view which schematically illustrates the structure of a semiconductor device in Embodiment 2 of the invention.

FIG. 20 is a schematic plan view which illustrates a situation that an impurity region SR, for isolation, illustrated in FIG. 19 surrounds the circumference of a region ARA where an array of high-breakdown-voltage lateral MOS transistors is arranged when the situation is viewed from the above.

FIG. 21 is a sectional perspective view which schematically illustrates the structure of a semiconductor device in Embodiment 3 of the invention.

FIG. 22 is a schematic plan view which illustrates a situation that a trench TRS, for isolation, illustrated in FIG. 21 surrounds the circumference of a region ARA where an array of high-breakdown-voltage lateral MOS transistors is arranged when the situation is viewed from the above.

FIG. 23 is a sectional view which schematically illustrates the structure of a semiconductor device in Embodiment 4 of the invention.

FIG. 24 is a chart which shows an electric field distribution in the structure illustrated in FIG. 23 when the structure is in a breakdown state, the distribution being based on isolation breakdown-voltage simulation.

FIG. 25 is a schematic sectional view which illustrates the structure of an IGBT having an n⁺ buried region and a p⁺ buried region.

FIG. 26 is a schematic sectional view which illustrates the structure of a diode having an n⁺ buried region and a p⁺ buried region.

FIG. 27 is a schematic sectional view which illustrates a first step in a process for producing a semiconductor device having a CMOS transistor, an LDMOS transistor, an IGBT and a diode.

FIG. 28 is a schematic sectional view which illustrates a second step in the process for producing a semiconductor device having a CMOS transistor, an LDMOS transistor, an IGBT and a diode.

FIG. 29 is a schematic sectional view which illustrates a third step in the process for producing a semiconductor device having a CMOS transistor, an LDMOS transistor, an IGBT and a diode.

FIG. 30 is a schematic sectional view which illustrates a structure obtained by omitting, from the structure illustrated in FIG. 1, its STI structure.

### DETAILED DESCRIPTION OF THE PREFERRED EMBODIMENTS

Hereinafter, embodiments of the invention will be described with reference to the drawings.

### Embodiment 1

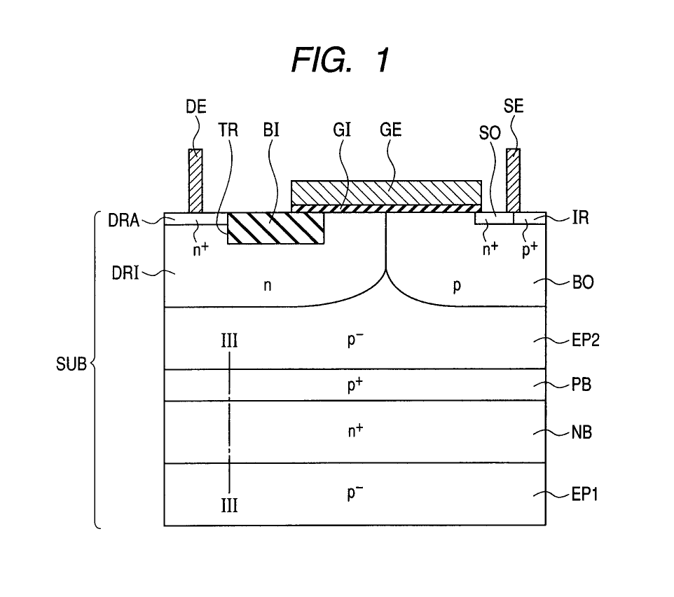

First, the structure of a semiconductor device of the present embodiment will be described with reference to FIG. 1.

As illustrated in FIG. 1, the semiconductor device of the embodiment has, for example, an LDMOS transistor. This semiconductor device mainly has a semiconductor substrate SUB, a p⁻ epitaxial region (first region) EP1, an n⁺ buried region (fifth region) NB, a p⁺ buried region (sixth region) PB, a p⁻ epitaxial region (second region) EP2, an n-type drift region (third region) DRI, a p-type body region (fourth region) BO, an n⁺ drain region DRA, an n⁺ source region, a gate electrode layer GE, and an STI structure TR and BI.

The semiconductor substrate SUB includes, for example, silicon. The semiconductor substrate SUB has a main surface (the upper surface of the substrate in FIG. 1). Inside the semiconductor substrate SUB, the p⁻ epitaxial region EP1 is formed.

The p⁻ epitaxial region EP2 is formed inside the semiconductor substrate SUB and at the main surface side of the p⁻ epitaxial region EP1. The n-type drift region DRI is formed inside the semiconductor substrate SUB and on the main surface side of the p⁻ epitaxial region EP2. The n-type drift region DRI is combined with the p⁻ epitaxial region EP2 to form, between the regions DRI and EP2, a pn junction extending along the main surface.

The p-type body region BO is formed inside the semiconductor substrate SUB and on the main surface side of the p⁻ epitaxial region EP2. The p-type body region BO is formed so as to contact the p⁻ epitaxial region EP2 and be further adjacent to the n-type drift region DRI, thereby forming a pn junction. The p-type body region BO has a higher p-type impurity concentration than that of the p⁻ epitaxial region EP2.

The n⁺ buried region NB is formed between the p⁻ epitaxial region EP1 and the p⁻ epitaxial region EP2. The n⁺ buried region NB is combined with the p⁻ epitaxial region EP1 to form a pn junction therebetween, and is further formed to separate the p⁻ epitaxial region EP1 and the p⁻ epitaxial region EP2 electrically from each other. The n⁺ buried region NB has a floating potential.

The p⁺ buried region PB is formed between the n⁺ buried region NB and the p⁻ epitaxial region EP2. The p⁺ buried region PB has a higher p-type impurity concentration than the p⁻ epitaxial region EP2. The p⁺ buried region PB is combined with the n⁺ buried region NB to form a pn junction therebetween, and is further combined with the p⁻ epitaxial region EP2 to form a pn junction therebetween.

The STI structure TR and BI has a trench TR and a buried insulating film BI. The trench TR is made in the main surface of the semiconductor substrate SUB and inside the n-type drift region DRI. The buried insulating film BI is buried in the trench TR.

The n⁺ drain region DRA is formed in the main surface of the semiconductor substrate SUB to contact the n-type drift region DRI, and further has a higher n-type impurity concentration than the n-type drift region DRI. The n⁺ drain region DRA is positioned by one side of the STI structure TR and BI that is opposite to the p-type body region BO side of the STI structure TR and BI, and is further formed to be adjacent to the STI structure TR and BI. A drain electrode DE is formed on the main surface of the semiconductor substrate SUB to be electrically coupled to the n⁺ drain region DRA.

An n⁺ source region SO is formed in the main surface of the semiconductor substrate SUB so as to be combined with the p-type body region BO to form a pn junction therebetween. A source electrode SE is formed on the main surface of the semiconductor substrate SUB so as to be electrically coupled to the n⁺ source region SO.

The gate electrode layer GE is formed over the p-type body region BO and the n-type drift region DRI that are sandwiched between the n⁺ drain region DRA and the n⁺ source region SO so as to interpose a gate insulating film between the layer GE and the regions BO and DRI. The gate electrode layer GE partially rides on the STI structure TR and BI.

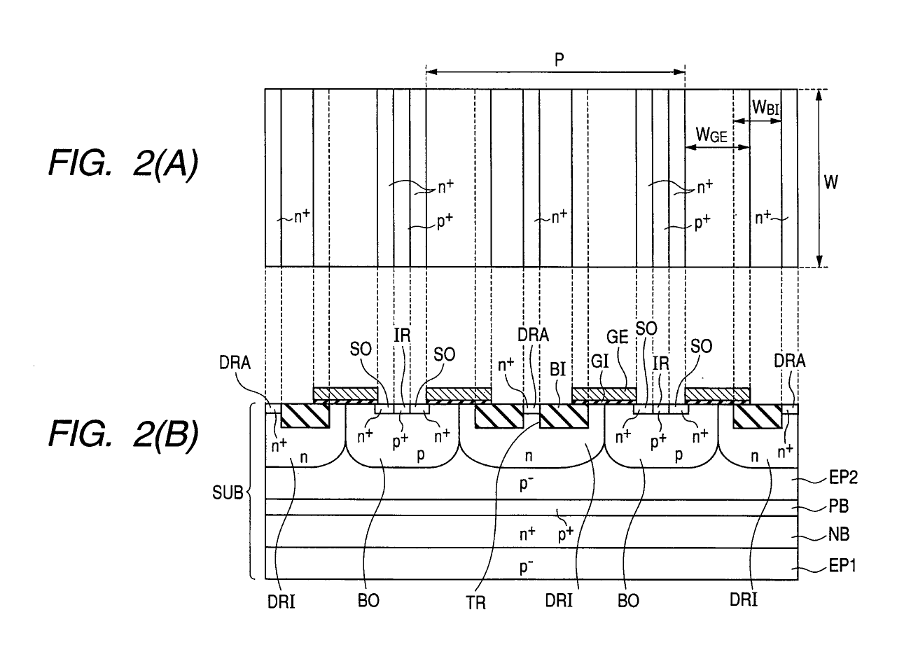

With reference to FIGS. 2(A) and 2(B), the following will describe an array arrangement of LDMOS transistors as illustrated in FIG. 1.

As illustrated in FIGS. 2(A) and 2(B), in an array arrangement of LDMOS transistors, drains and sources are repeated. In the present embodiment, a type of the array is shown as an example, and the type is a type having a structure wherein source regions SO are arranged at both sides of each drain region DRA as a center. The structure is repeated at a pitch P between the predetermined ones of the source regions SO. In, for example, a reverse type having a structure wherein drain regions DRA are arranged at both sides of each source region SO as a center, the structure is repeated at a pitch P between the drain regions DRA as shown in FIGS. 2(A) and 2(B). The width of the LDMOS transistors is defined as a length represented by reference symbol W FIG. 2(A). Thus, the size of the two-dimensional layout of the LDMOS transistors is adjusted by controlling the number of the sources/drains, which is defined by the pitch P, and the width W so as to gain a desired electric current power.

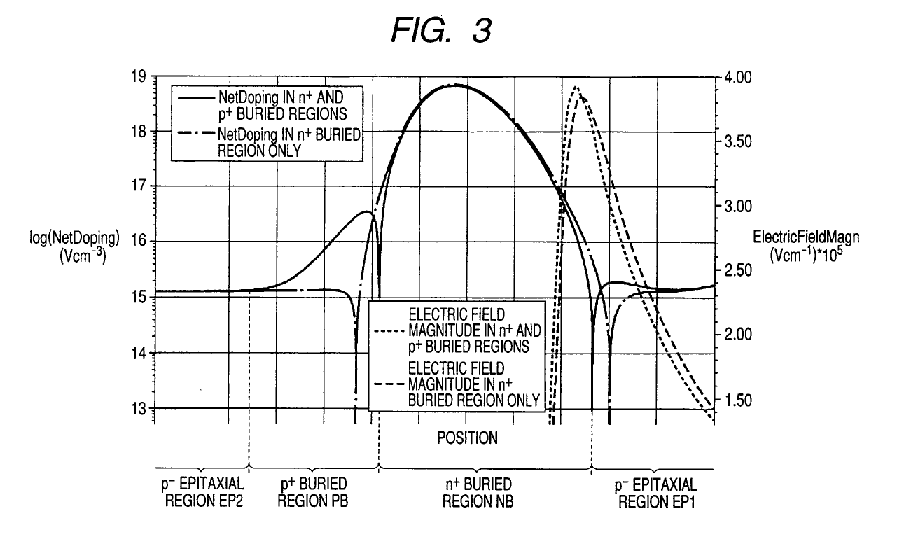

With reference to FIG. 3, the following will describe an impurity concentration distribution in each of the regions in the semiconductor device of the embodiment illustrated FIG. 1.

As illustrated in FIG. 3, a curve represented by a solid line therein shows an impurity concentration distribution in a portion along line III-III in FIG. 1. The p⁻ epitaxial region EP2 has a substantially constant (uniform) p-type impurity concentration along the depth direction from the main surface side of the semiconductor substrate SUB to the rear surface side thereof.

The p⁺ buried region PB has a higher p-type impurity concentration than the p⁻ epitaxial region EP2. The p-type impurity concentration in the p⁺ buried region PB gradually becomes higher from the p⁻ epitaxial region EP2 side thereof toward the rear surface of the substrate, and reaches a peak in the vicinity of the n⁺ buried region NB. The p-type impurity concentration in the p⁺ buried region PB is offset with the n-type impurity concentration in the n⁺ buried region NB at the n⁺ buried region NB side of the concentration peak, so as to be sharply decreased.

The n-type impurity concentration in the n⁺ buried region NB gradually becomes higher from the p⁺ buried region PB side thereof toward the rear surface of the substrate to reach a peak. At the p⁻ epitaxial region EP1 side of the region NB from the concentration peak, the n-type impurity concentration decreases gradually. The n-type impurity concentration at the concentration peak in the n⁺ buried region NB is higher than the p-type impurity concentration at the concentration peak in the p⁺ buried region PB.

The p⁺ epitaxial region EP1 has a substantially constant (uniform) p-type impurity concentration along the depth direction from the n⁺ buried region NB side thereof toward the rear surface of the substrate. The p-type impurity concentration in the p⁻ epitaxial region EP1 is substantially equal to the p-type impurity concentration in the p⁻ epitaxial region EP2. Specific values of the p-type impurity concentrations in the p⁻ epitaxial regions EP1 and EP2 are each aimed at a target value of, for example, 1×10¹⁵ cm⁻³; for this purpose, the values are each adjusted to set the resistivity of the region into the range of 10±1.5 Ω·cm.

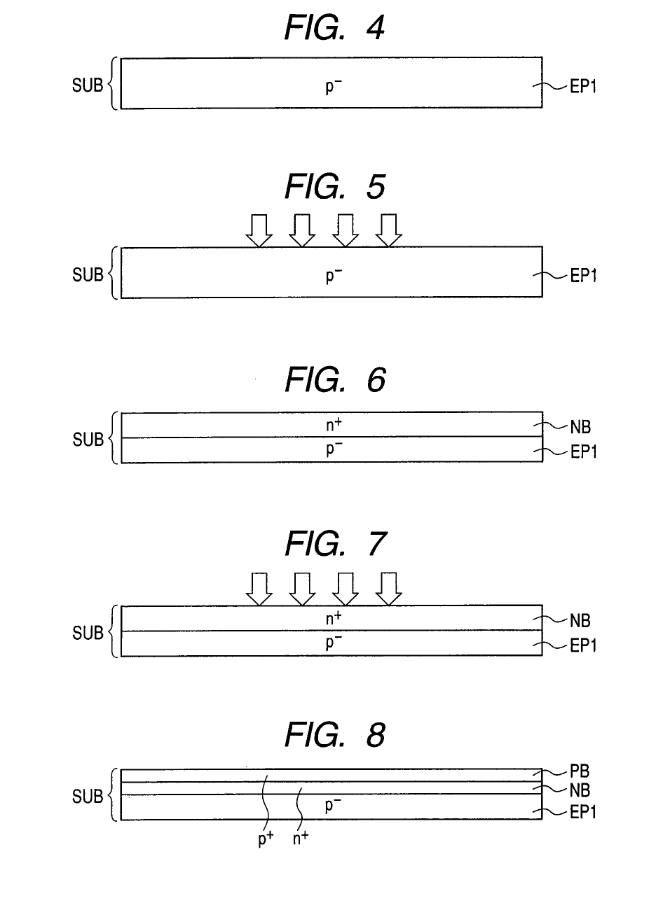

The following will describe a process for producing a semiconductor device of the embodiment with reference to FIGS. 4 to 9, and FIG. 1. As illustrated in FIG. 4, a p⁻ epitaxial region EP1 is first formed in a semiconductor substrate SUB by epitaxial growth.

As illustrated in FIG. 5, n-type ions are implanted onto the surface of the p⁻ epitaxial region EP1 by ion implantation.

As illustrated in FIG. 6, the workpiece is annealed so that the n-type ions implanted in the p⁻ epitaxial region EP1 are diffused, thereby forming an n⁺ buried region NB on the surface of the p⁻ epitaxial region EP1.

As illustrated in FIG. 7, p-type ions are implanted into the surface of the n⁺ buried region NB.

As illustrated in FIG. 8, the workpiece is annealed so that the p-type ions implanted in the n⁺ buried region NB are diffused, thereby forming a p⁺ buried region PB on the surface of the n⁺ buried region NB.

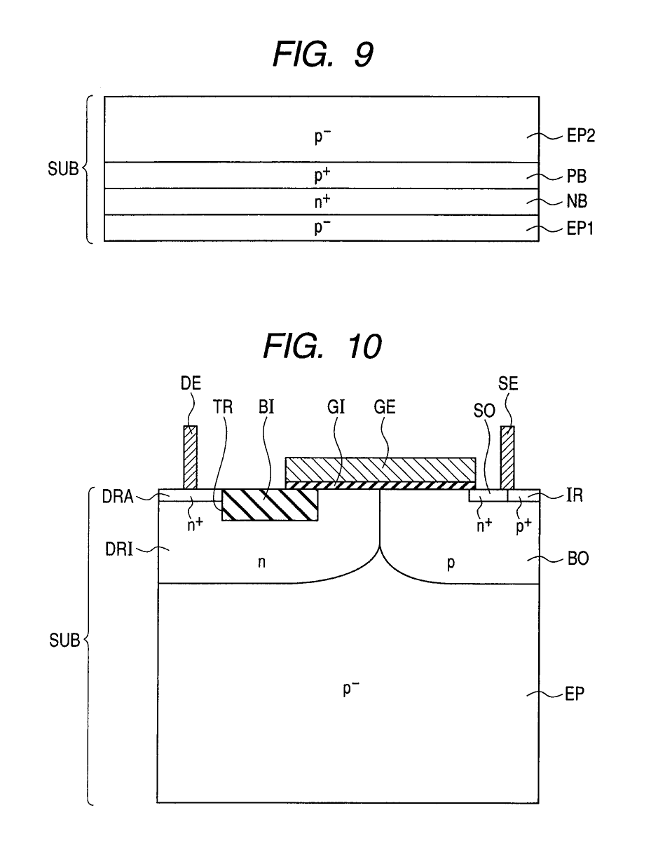

As illustrated in FIG. 9, a p⁻ epitaxial region EP2 is formed on the p⁺ buried region by epitaxial growth.

Thereafter, as has been illustrated in FIG. 1, an n-type drift region DRI, a p-type body region BO and so on are formed in the p⁻ epitaxial region EP2. In this way, the semiconductor device of the embodiment is produced.

With reference to FIGS. 10 to 18, the following will describe effects and advantages of the embodiment through a comparison thereof with those of Comparative Examples 1 to 3, and others.

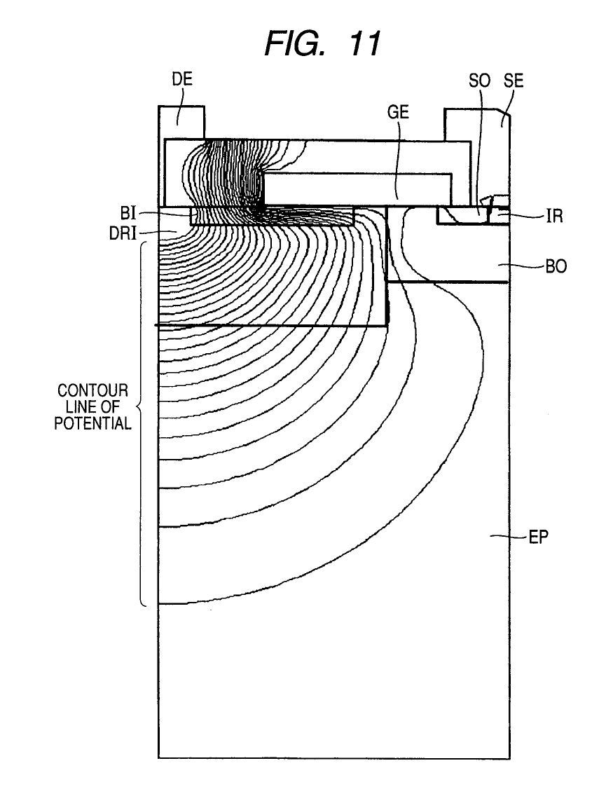

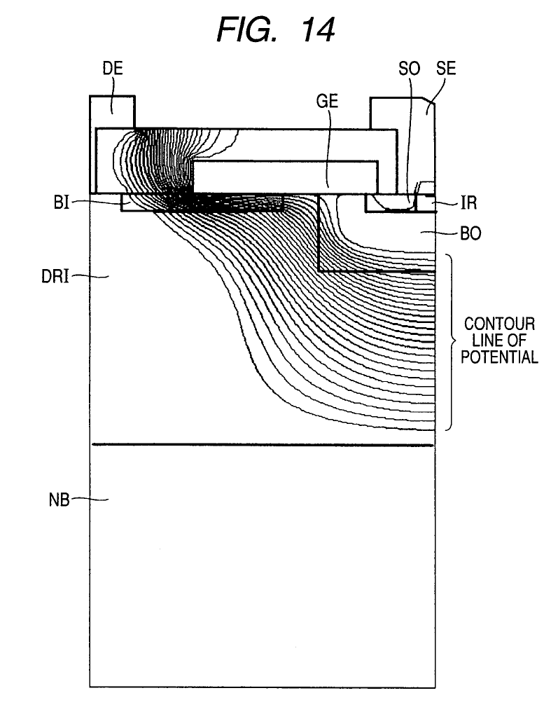

Comparative Example 1 illustrated in FIG. 10 has a structure obtained by omitting, from the structure of the embodiment illustrated in FIG. 1, the n⁺ buried region NB and the p⁺ buried region PB. In Comparative Example 1, an n-type drift region DRI contacts the upper of a p⁻ epitaxial region EP, whereby the example has a RESURF structure. Therefore, when the example is in the state that a reverse bias is applied to the p⁻ epitaxial region EP and the n-type drift region DRI so that the example undergoes a breakdown (the state will be referred to merely as a “breakdown state” hereinafter), a depletion layer spreads in the p⁻ epitaxial region EP underneath the n-type drift region DRI as illustrated in FIG. 11. Thus, the example can have a high breakdown voltage. Plural curves shown in FIG. 11 are contour lines of the potential inside the depletion layer. The same matter is applied to plural curves shown in FIGS. 14 ad 16.

However, the structure of Comparative Example 1 has a problem that the structure is not easily used as a high-side element since its source electrode SE (or its p-type body region BO) and the p-epitaxial region EP are not isolated electrically from each other.

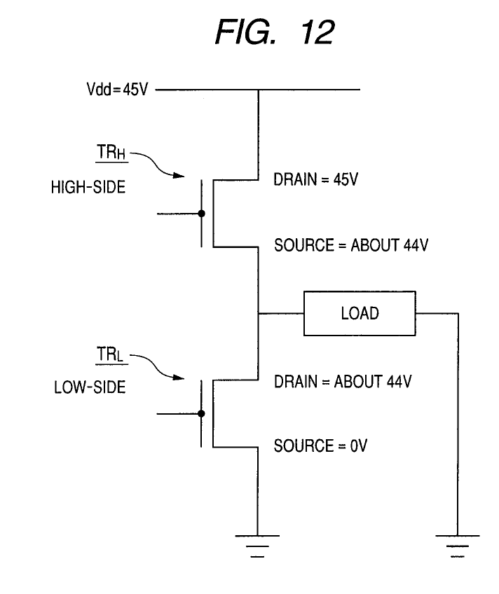

Specifically, in the case of using the transistor of Comparative Example 1 illustrated in FIG. 10 as a high-side element TR_{H} in FIG. 12, the application of a power source voltage VDD of, e.g., 45 V to the drain of the transistor TR_{H} causes a voltage of about 44V to be applied to the source. In the transistor of Comparative Example 1 illustrated in FIG. 10, the source electrode SE (or the p-type body region) and the p⁻ epitaxial region EP are not isolated electrically from each other. Therefore, when the source voltage of the transistor TR_{H} is turned into a “high” value of 44 V, the ground potential (GND), which is the potential of the substrate coupled electrically to the p⁻ epitaxial region EP, becomes instable. When the ground potential is instable, the potential of the source (back gate) which is the ground potential of a low-side element TR_{L} illustrated in FIG. 12 also becomes instable. As a result, the low-side element TR_{L} malfunctions.

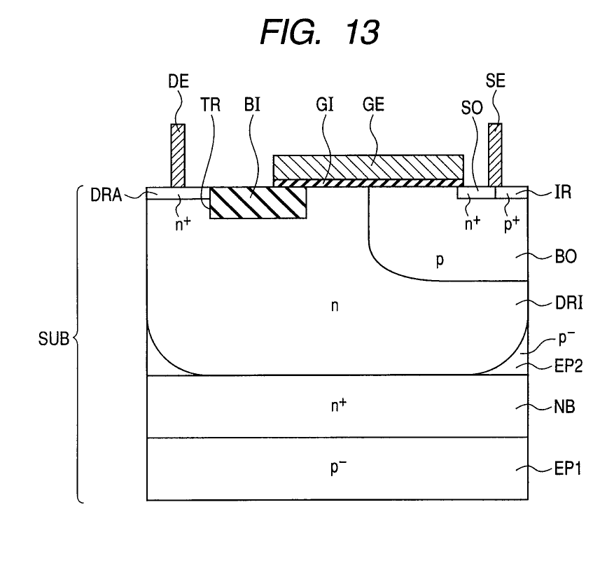

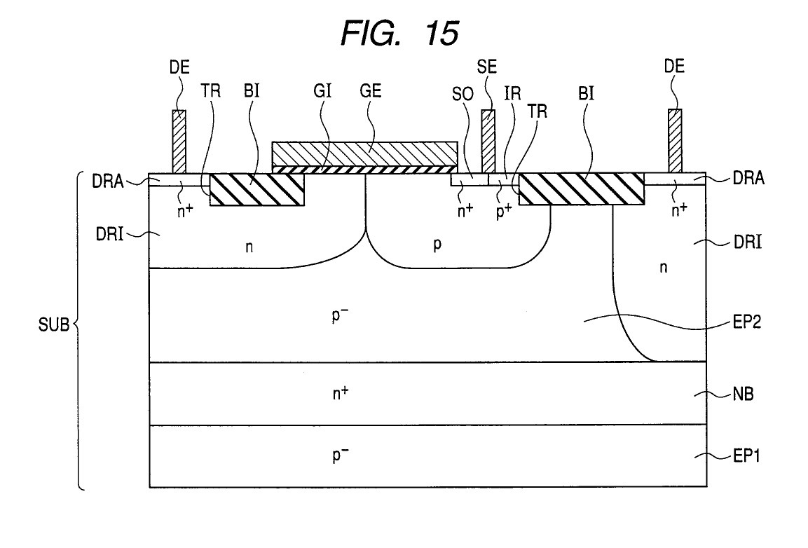

Thus, the following two structures are supposed as a structure wherein an n-type isolation region is formed for isolating a p⁻ epitaxial region and a source electrode (or a p-type body region) electrically from each other: the structure of Comparative Example 2 illustrated in FIG. 13; and that of Comparative Example 3 illustrated in FIG. 15.

The structure of Comparative Example 2 illustrated FIG. 13 is a structure wherein an n⁺ buried region NB is formed as an n-type isolation region as described above and further an n-type drift region DRI is not only arranged underneath an n⁺ drain region DRA but also extended around the underneath of a p-type body region BO, so as to reach the n⁺ buried region NB.

However, the structure of Comparative Example 2 is not any RESURF structure. Therefore, when the structure is in a breakdown state, an electric field concentrates into the vicinity of the junction between the p-type body region BO and the n-type drift region DRI. In this way, the breakdown voltage of Comparative Example 2 is lower than that of Comparative Example 1.

In order to raise the breakdown voltage of the structure of Comparative Example 2, it is necessary to decrease the concentration of the impurity in the n-type drift region DRI as illustrated in FIG. 14. However, the decrease thereof in the n-type drift region DRI results in a rise in the on-resistance. Thus, it becomes necessary to make the element size large.

The structure of Comparative Example 3 illustrated in FIG. 15 is a structure wherein an n⁺ buried region NB is formed as an n-type isolation region as described above and further the n⁺ buried region NB is electrically short-circuited with a drain electrode DE.

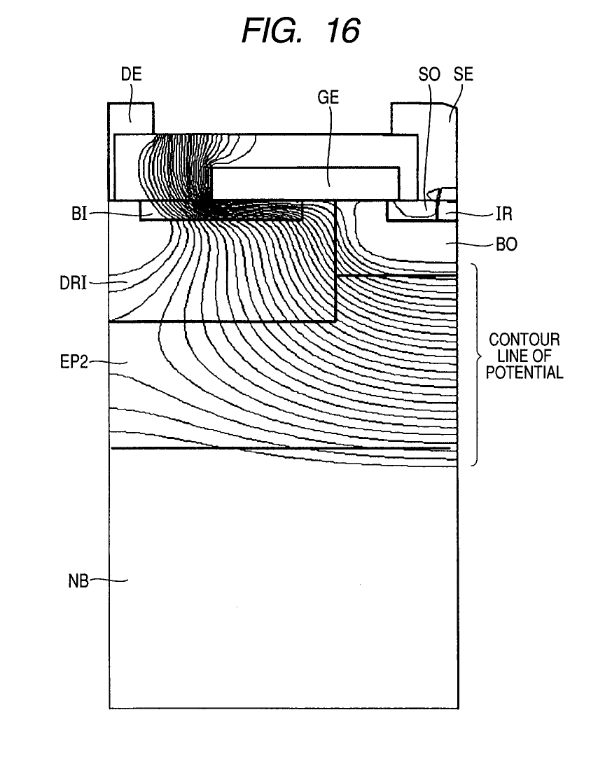

In the structure of Comparative Example 3, the n⁺ buried region NB is at a level of the drain potential. Therefore, when the structure is in a breakdown state, a depletion layer generated in a junction region between the n⁺ buried region NB and the p⁻ epitaxial region EP2 and a depletion layer generated in a junction region between the p⁻ epitaxial region EP2 and the n-type drift region DRI undergo punchthrough antecedently as illustrated in FIG. 16. Thus, a potential difference is generated between the n⁺ buried region NB and the n⁺ source region SO. As a result thereof, electric-field-concentration is caused in the vicinity of the junction between the p-type body region BO and the n-type drift region DRI, so that Comparative Example 3 has a lower breakdown voltage than Comparative Example 1.

Against the above, in the structure of the embodiment illustrated in FIG. 1, the p⁻ epitaxial region EP1 and the source electrode SE (or the p-type body region BO) are isolated electrically from each other by the n⁺ buried region NB. For this reason, even when the embodiment is used as a high-side element, malfunctions can be reduced.

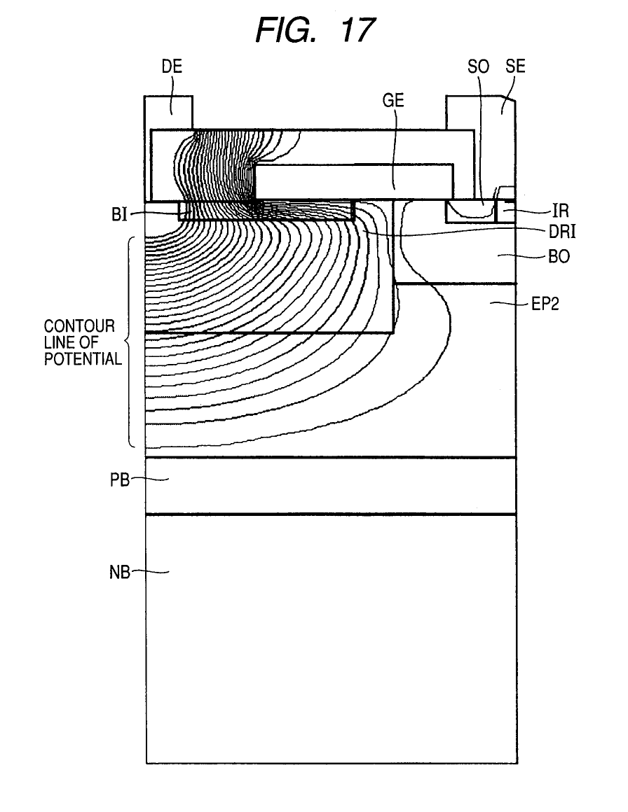

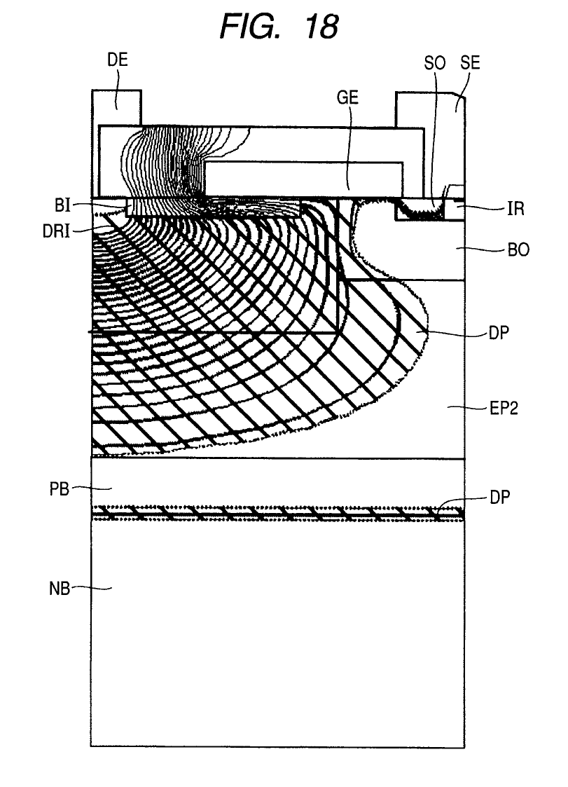

In the embodiment, the n-type drift region DRI is combined with the p⁻ epitaxial region EP2 to form, therebetween, a pn junction extending along the main surface of the semiconductor substrate SUB. Moreover, the p⁻ epitaxial region EP2 has a lower p-type impurity concentration than the p-type body region BO. As illustrated in FIG. 17, therefore, when the embodiment is in a breakdown state, a depletion layer spreads from the pn junction between the n-type drift region DRI and the p⁻ epitaxial region EP2 toward the p⁻ epitaxial region EP2. Thus, the embodiment can have a high breakdown voltage. A region hatched with thick lines in FIG. 18 is a depletion layer DP in FIG. 17, which is generated in a breakdown state.

The p-type impurity concentration in the p⁻ epitaxial region EP2 wherein the depletion layer DP spreads is substantially uniform in the region EP2. Thus, a uniform electric field can be obtained inside the depletion layer DP.

In the embodiment, the p⁺ buried region PB, which has a higher p-type impurity concentration than the p⁻ epichlorohydrin region EP2, is formed between the n⁺ buried region NB and the p⁻ epitaxial region EP2. When the transistor is also in a breakdown state, the p⁺ buried region PB restrains the depletion layer spread from the pn junction between the n-type drift region DRI and the p⁻ epitaxial region EP2 toward the p⁻ epitaxial region EP2 from linking with the depletion layer generated in the pn junction between the p⁺ buried region PB and the n⁺ buried layer NB, as illustrated in FIG. 18. In this way, the generation of punchthrough is restrained so that the transistor of the embodiment can keep a high breakdown voltage.

### Embodiment 2

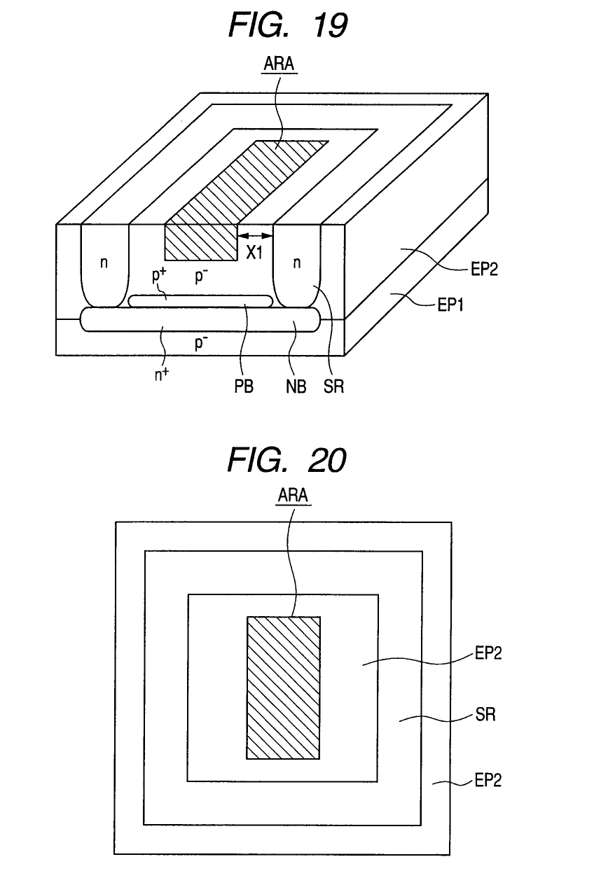

In an analog/digital consolidated technique, an LDMOS transistor as in Embodiment 1 may be formed together with a complementary MOS (CMOS), a bipolar transistor, a diode, a memory element and others on a single chip through the same process. When the transistor or transistors of Embodiment 1 are laid out on such a chip, it is necessary to isolate the transistor(s) electrically from the other elements. In the present embodiment, a structure for the electrical isolation will be described with reference to FIGS. 19 and 20.

As illustrated in FIGS. 19 and 20, in the embodiment, an n-type isolation region (impurity region for isolation) SR is formed so as to surround the circumference of an area ARA when the structure of the embodiment is viewed from the above, the area ARA being an area where an array of LDMOS transistors as illustrated in FIGS. 2(A) and 2(B) is arranged. The n-type isolation region SR is formed in a semiconductor substrate SUB to be combined with a p⁻ epitaxial region EP2, thereby forming a pn junction therebetween. The region SR is extended from the main surface of the semiconductor substrate SUB to reach an n⁺ buried region NB. By the n-type isolation region SR, the array of the LDMOS transistors is isolated electrically from the other elements. The n-type isolation region SR has a floating potential.

In the embodiment, the n-type isolation region SR does not contact the p⁺ buried region, and a p⁻ epitaxial region EP2 is positioned between the n-type isolation region SR and the p⁺ buried region PB.

The n-type isolation region SR may be formed to contact the n⁺ buried region NB by implanting an n-type impurity into the vicinity of the main surface of the semiconductor substrate SUB to give a high concentration and then annealing the workpiece at a high temperature for a long period to diffuse the impurity. The n-type isolation region SR may be formed to contact the n⁺ buried region NB by implanting an n-type impurity into a deep position of the p⁻ epitaxial region EP2 at a high energy and then annealing the workpiece to diffuse the impurity.

When the n-type impurity in the n-type isolation region SR diffuses into the region ARA, where the array of the LDMOS transistors is arranged, the impurity produces an effect onto the transistor performance. Thus, it is necessary to design the interval X1 between the n-type isolation region SR and the array-arranged region ARA into such a value that no effect is produced onto the transistor performance.

### Embodiment 3

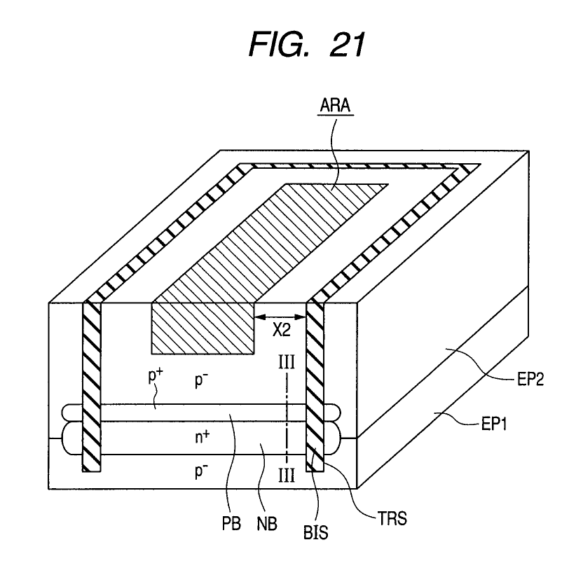

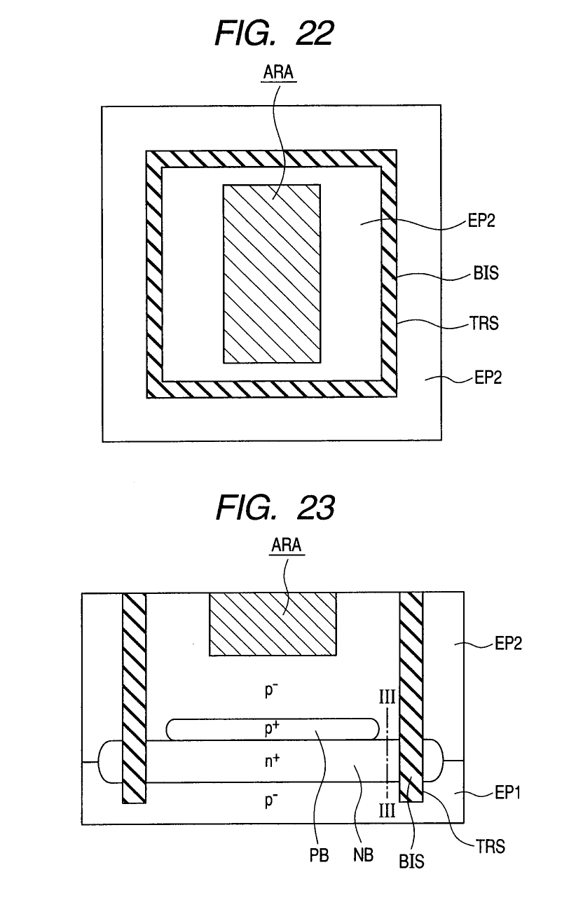

As illustrated in FIG. 21 and FIG. 22, in the present embodiment, a trench isolation is formed for isolating an area ARA where an array of LDMOS transistors is arranged electrically from other elements. The trench isolation has an isolating trench TRS and a buried (or filled) insulating layer BIS.

The isolating trench TRS surrounds the circumference of the LDMOS-transistor-array-arranged area ARA when the structure of the embodiment is viewed from the above. The isolating trench TRS penetrates from the main surface of the present semiconductor substrate SUB through a p⁺ buried region PB to reach an n⁺ buried region NB.

It is preferred that the isolating trench TRS penetrates through the n⁺ buried region NB also to reach a p⁻ epitaxial region EP1. The penetration of the isolating trench TRS through the n⁺ buried region NB, as described herein, makes it possible to make the n⁺ buried region NB so as to have a floating potential.

The buried insulating layer BIS is formed to be filled into the isolating trench TRS. In the embodiment, the trench isolation is used to isolate the array-arranged region ARA electrically from the other elements; therefore, it is unnecessary to consider an effect of n-type impurity diffusion onto the transistors as in the case of forming the n-type isolating region SR in Embodiment 2. In this case, therefore, the interval between the array-arranged region ARA and the trench isolation can be made narrower than in the case of the diffusion isolation in Embodiment 2 (the interval may be set to, for example, zero). Thus, in the embodiment, chip shrinkage can be more satisfactorily attained than in Embodiment 2.

### Embodiment 4

As illustrated in FIG. 23, the structure of the present embodiment is different from that of Embodiment 3 in that an isolating trench TRS for trench isolation does not contact a p⁺ buried region PB (the trench TRS does not penetrate through the region PB). In the embodiment, therefore, a p⁻ epitaxial region EP2 is positioned between the isolating trench TRS and the p⁺ buried region PB.

The structural elements of the embodiment other than the above are substantially the same as illustrated in FIGS. 21 and 22. Thus, the same reference symbols are attached to the same elements, and overlapping descriptions are not repeated.

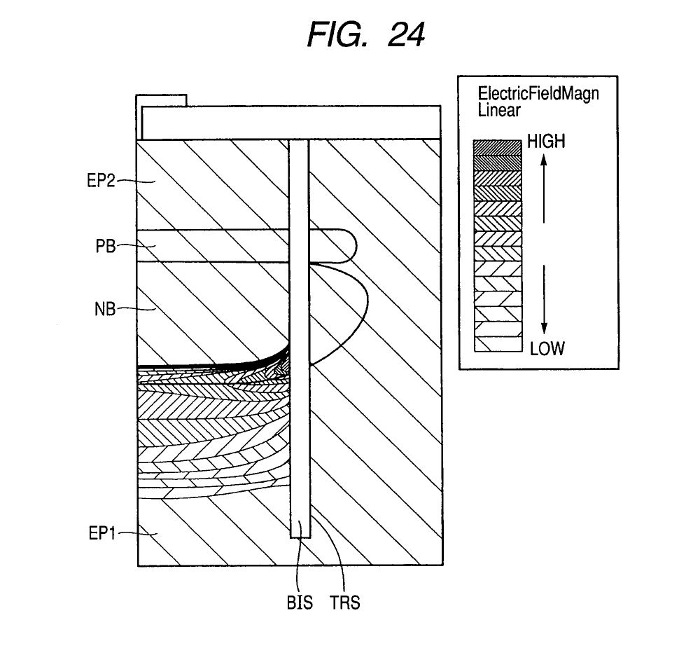

When lateral direction isolation is attained by a trench isolation as in Embodiment 3, the breakdown voltage between the elements (LDMOS transistors) and the substrate is decided by the junction breakdown voltage between the n⁺ buried region NB and the p⁻ epitaxial region EP1. It is understood from an electric field magnitude distribution in FIG. 24, which is based on a simulation, that the vicinity of the interface between the n⁺ buried region NB and the p⁻ epitaxial region EP1 that contacts the trench isolation is at a level of the highest electric field magnitude.

A structure suitable for relieving the high electric field magnitude to obtain an isolating breakdown voltage as high as possible is a structure wherein only the n⁺ buried region NB is overlapped with the trench isolation without overlapping the p⁺ buried region PB with the trench isolation.

FIG. 3 shows a comparison between an impurity concentration profile in a case where only the n⁺ buried region NB is overlapped therewith and that in a case where both the n⁺ buried region NB and the p⁺ buried region PB are overlapped therewith, and also shows a comparison between the electric field magnification of the former case and that of the latter case when the structures in the two cases are each in a breakdown state. In FIG. 3, the impurity concentration distribution represented by a solid line corresponds to an impurity concentration distribution in a portion along line in FIG. 21; and in FIG. 3, the impurity concentration distribution represented by an alternate long and short dash line corresponds to an impurity concentration distribution in a portion along line in FIG. 23. In FIG. 3, a broken line having short pieces represents an electric field magnification distribution in the interface between the n⁺ buried region NB and p⁻ epitaxial region EP1 in the structure in FIG. 21; and in FIG. 3, a broken line having long pieces represents an electric field magnification distribution in the interface between the n⁺ buried region NB and p″ epitaxial region EP1 in the structure in FIG. 23.

As is evident from FIG. 3, when both of the n⁺ buried region NB and the p⁺ buried region PB are overlapped with the trench isolation, the p-type impurity in the p⁺ buried region PB diffuse in the substrate direction (i.e., toward the p⁻ epitaxial region EP1 side) also. For this reason, in the case, the p-type impurity concentration in the interface between the n⁺ buried region NB and the p⁻ epitaxial region EP1 is higher than in the case where only the n⁺ buried region NB is overlapped with the trench isolation. As described above, the breakdown voltage between any substrate and an element thereon is decided by the joint breakdown voltage of this region. Thus, the electric field magnification (represented by the broken line the pieces of which are long) of the structure illustrated in FIG. 23 wherein only the n⁺ buried region NB, which has a loose joint, contacts the trench isolation, is lower than that (represented by the broken line the pieces of which are short) of the structure illustrated in FIG. 21 wherein both the n⁺ buried region NB and the p⁺ buried region PB contact the trench isolation, so as to have a higher breakdown voltage. Thus, the structure in FIG. 23, wherein the p⁺ buried region PB is not overlapped with the trench isolation, has a higher isolating breakdown voltage.

### (Others)

The high-breakdown-voltage laterally diffused MOS transistors that have been described in Embodiments 1 to 4 are LDMOS transistors. However, any high-breakdown-voltage laterally diffused MOS transistor used in the invention may be an insulated gate bipolar transistor (IGBT) or a diode.

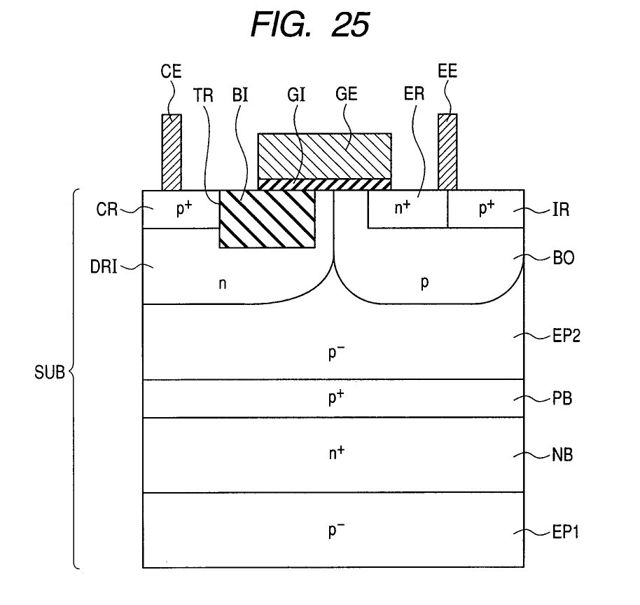

FIG. 25 illustrates the structure of an IGBT having an n-type buried region NB and a p-type buried region PB. The IGBT is different from the structure illustrated in FIG. 1 in that the n⁺ drain region DRA of the LDMOS transistor illustrated in FIG. 1 is rendered a p⁺ collector region CR and further the n⁺ source region SO is rendered an n⁺ emitter region ER. Following this difference, the drain electrode DE is changed to a collector electrode CE and the source electrode SE is changed to an emitter electrode EE.

The structural elements of the IGBT illustrated in FIG. 25 other than the above are substantially equivalent to those of the LDMOS transistor illustrated in FIG. 1. Thus, the same reference symbols are attached to the same elements, and overlapping descriptions are not repeated.

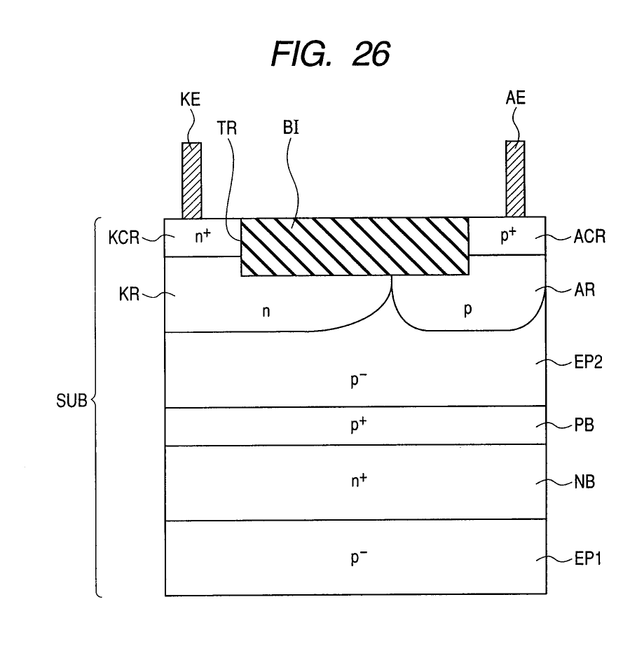

FIG. 26 illustrates the structure of a diode having an n-type buried region NB and a p-type buried region PB. The diode has an n-type cathode region KR and a p-type anode area AR that are combined with each other to form a p n junction therebetween. The n-type cathode area KR and the p-type anode area AR are formed on the main surface side of a p⁻ epitaxial region EP2 to contact the p⁻ epitaxial region EP2.

An n⁺ cathode contact region KCR is formed in the main surface of the present semiconductor substrate SUB inside the n-type cathode area KR, and a p⁺ anode contact region ACR is formed in the main surface of the semiconductor substrate SUB inside the p-type anode area AR. A cathode electrode KE is formed on the main surface of the semiconductor substrate SUB to be coupled electrically to the n⁺ cathode contact region KCR. An anode electrode AE is formed on the main surface of the semiconductor substrate SUB to be coupled electrically to the p⁺ anode contact region ACR. A gate insulating film GI, a gate electrode layer GE, and a p⁻ impurity region IR are omitted.

The structural elements of the diode illustrated in FIG. 26 other than the above are substantially equivalent to those of the LDMOS transistor illustrated in FIG. 1. Thus, the same reference symbols are attached to the same elements, and overlapping descriptions are not repeated.

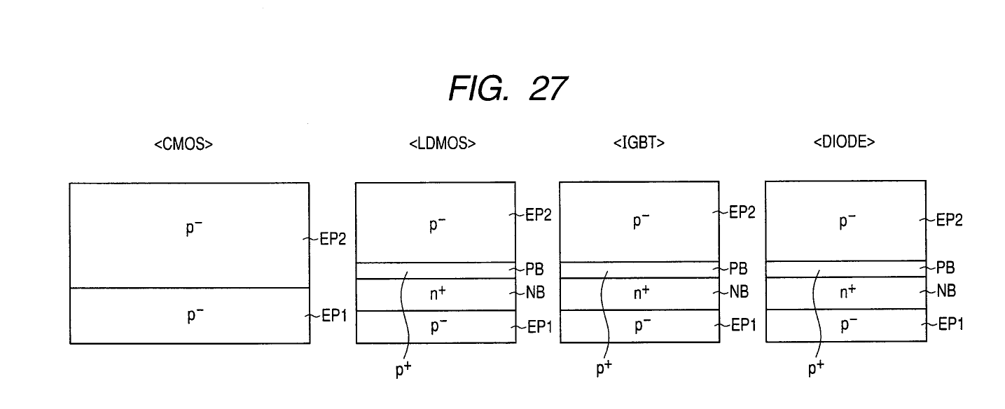

With reference to FIGS. 27 to 29, the following will describe a process for producing a semiconductor device having a CMOS transistor, an LDMOS transistor, an IGBT, and a diode.

As illustrated in FIG. 27, in this production process, regions where the LDMOS transistor, the IGBT, and the diode are to be formed, respectively, are caused to undergo the steps illustrated in FIGS. 4 to 9. This manner gives a lamination of a p⁻ epitaxial region EP1, an n⁺ buried region NB, a p⁺ buried region PB and a p⁻ epitaxial region EP2 in each of the regions, where the LDMOS transistor, the IGBT, and the diode are to be formed, respectively.

In the region where the CMOS transistor is to be formed, a lamination of p⁻ epitaxial regions EP1 and EP2 is formed by conducting the steps illustrated in FIGS. 4 to 9 without forming the n⁺ buried region NB and the p⁺ buried region PB.

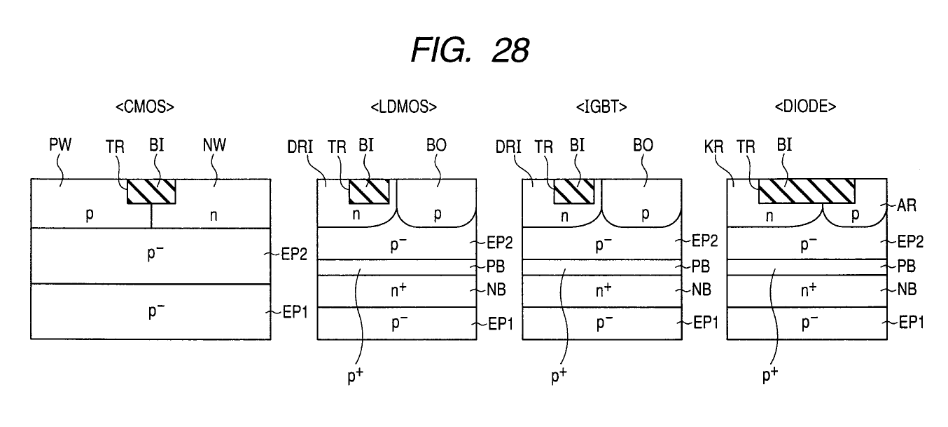

As illustrated in FIG. 28, in the region where the CMOS transistor is to be formed, an n-type well region NW, a p-type well region PW and an STI structure TR and BI are formed on the p⁻ epitaxial region EP2. In the region where the LDMOS transistor and the IGBT are each to be formed, an n-type drift region DRI, a p-type body region BO and an STI structure TR and BI are formed on the p⁻ epitaxial region EP2. In the region where the diode is to be formed, an n-type cathode region KR, a p-type anode region AR, and an STI structure TR and BI are formed on the p⁻ epitaxial region EP2.

It is allowable to form the p-type well region PW of the CMOS transistor, the p-type body regions BO of the LDMOS transistor and the IGBT, and the p-type anode region AR of the diode in the same step. It is also allowable to form the n-type drift regions DRI of the LDMOS transistor and the IGBT, and the n-type cathode region KR of the diode in the same step. At this time, the n-type drift regions DRI are formed under implanting conditions for realizing optimal RESURF conditions. The n-type drift regions DRI and the n-type cathode region KR generally have a lower impurity concentration than the n-type well region NW of the CMOS transistor. The individual STI structures TR and BI in the CMOS transistor, the LDMOS transistor, the IGBT and the diode may be formed in the same step.

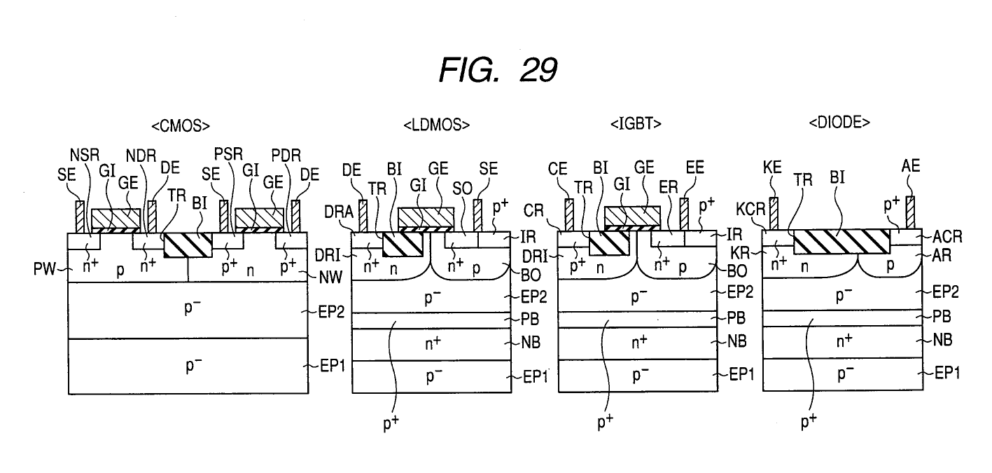

As illustrated in FIG. 29, in the region where the CMOS is to be formed, the following are formed: a gate insulating film GI, a gate electrode layer GE, an n⁺ source region NSR, an n⁺ drain region NDR, a p⁺ source region PSR, a p⁺ drain region PDR, a source electrode SE, and a drain electrode DE. In the region where the LDMOS is to be formed, the following are formed: a gate insulating film GI, a gate electrode layer GE, an n⁺ source region SO, an n⁺ drain region DRA, a p⁺ impurity region IR, a source electrode SE, and a drain electrode DE.

In the region where the IGBT is to be formed, the following are formed: a gate insulating film GI, a gate electrode layer GE, a p⁺ collector region CR, an n⁺ emitter region ER, a p⁺ impurity region IR, a collector electrode CE, and an emitter electrode EE. In the region where the diode is to be formed, the following are formed: an n⁺ cathode collector area KCR, a p⁺ anode collector area ACR, a cathode electrode KE, and an anode electrode AE. In this way, a semiconductor device can be produced which has the CMOS transistor, the LDMOS transistor, the IGBT, and the diode.

In the embodiment, instead of the STI structures TR and BI, field insulating films (for example, field oxide films) may be formed by local oxidation of silicone (LOCOS). The use of STI structures TR and BI or field insulating films in such as manner makes it possible to give a field plate effect using gate electrode layers GE. Thus, a further increase in the breakdown voltage can be realized.

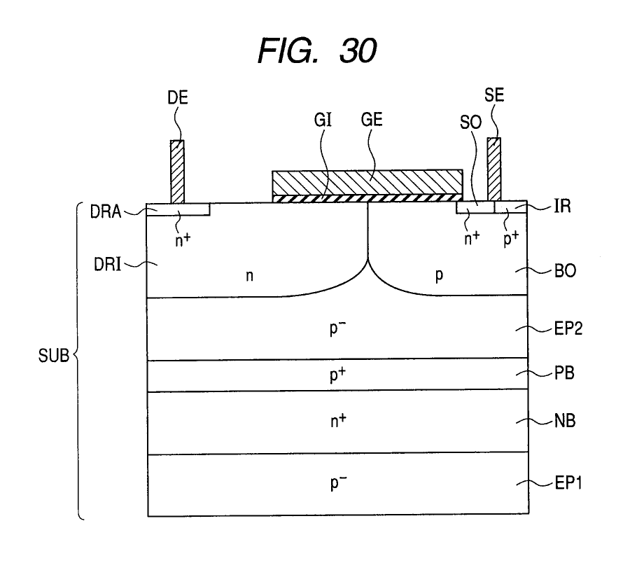

As illustrated in FIG. 30, an n⁺ buried region NB and a p⁺ buried region PB may be applied to a structure wherein any STI structure TR and BI and any field oxide film are omitted.

The n⁺ buried region NB and the p⁺ buried region PB are an n⁺ impurity region and a p⁺ impurity region that are each formed by ion implantation, respectively.

It should be understood that the embodiments disclosed herein are illustrative in all points and not restrictive. The scope of the invention is specified not by the above-mentioned description but by the appended claims. It is intended that the scope includes every modification having a meaning and a scope equivalent to those of the claims.

The invention can be in particular favorably applied to a semiconductor device having a lateral element.

What is claimed is:

1. A semiconductor device, comprising:
a semiconductor substrate having a main surface;
a first conductive type first region formed in the semiconductor substrate;
a first conductive type second region formed in the semiconductor substrate and at the main surface side of the first region;
a second conductive type third region formed in the semiconductor substrate and at the main surface side of the second region, and further combined with the second region to form a pn junction therebetween;
a first conductive type fourth region formed in the semiconductor substrate to contact the second region and be further adjacent to the third region at the main surface side of the second region, and further having a higher first conductive type impurity concentration than that of the second region;
a second conductive type fifth region formed in the semiconductor substrate between the first region and the second region to isolate the first region and the second region electrically from each other, and further formed to have a floating potential; and
a first conductive type sixth region formed in the semiconductor substrate between the fifth region and the second region and further having a higher first conductive type impurity concentration than that of the second region.

2. The semiconductor device according to claim 1, further comprising a second conductive type impurity region for isolation which surrounds, in the main surface, the circumference of a region where a lateral element containing the second, the third and the fourth regions is formed and which reaches from the main surface to the fifth region.

3. The semiconductor device according to claim 1, wherein the semiconductor substrate has a trench for isolation which surrounds, in the main surface, the circumference of a region where a lateral element containing the second, the third and the fourth regions is formed and which reaches from the main surface at least to the fifth region.

4. The semiconductor device according to claim 3, wherein the isolation trench penetrates through the sixth region to reach the fifth region.

5. The semiconductor device according to claim 3, wherein the isolation trench reaches the fifth region without contacting the sixth region.

6. The semiconductor device according to claim 1, further comprising:
a first conductive type drain region formed in the main surface to contact the third region and further having a higher first conductive type impurity concentration than that of the third region;
a first conductive type source region formed in the main surface to be combined with the fourth region to form a pn junction therebetween; and
a gate electrode formed to be electrically insulated from a portion of the fourth region sandwiched between the drain region and the source region and be opposed to the portion.

7. The semiconductor device according to claim 1, further comprising:
a second conductive type collector region formed in the main surface to be combined with the third region to form a pn junction therebetween;
a first conductive type emitter region formed in the main surface to be combined with the fourth region to form a pn junction therebetween; and
a gate electrode formed to be electrically insulated from a portion of the fourth region sandwiched between the collector region and the emitter region and be opposed to the portion.

8. The semiconductor device according to claim 1, further comprising:
a first conductive type cathode contact region formed in the main surface to contact the third region, and further having a higher first conductive type impurity concentration than that of the third region; and
a second conductive type anode contact region formed in the main surface to contact the fourth region and further having a higher second conductive type impurity concentration than that of the fourth region.

9. The semiconductor device according to claim 1, further comprising an insulating film formed selectively over the main surface inside the third region.
